(19) United States
(12) Patent Application Publication
(10) Pub. No.: US 2025/0160001 A1
(43) Pub. Date: May 15, 2025

(54) LOW TEMPERATURE ETCH-BASED METAL TRANSFER METHOD AND HIGH-QUALITY SOURCE-DRAIN FORMATION METHOD

(71) Applicant: KOREA UNIVERSITY RESEARCH AND BUSINESS FOUNDATION, Seoul (KR)

(72) Inventors: Hyun-Yong YU, Seoul (KR); Kyu Hyun HAN, Seoul (KR)

(21) Appl. No.: 18/947,189

(22) Filed: Nov. 14, 2024

(30) Foreign Application Priority Data
Nov. 14, 2023 (KR) 10-2023-0157649
Dec. 5, 2023 (KR) 10-2023-0174602

(51) Int. Cl. H01L 29/66; H01L 21/44

(52) U.S. Cl. CPC H10D 99/00; H01L 21/44

(57) ABSTRACT

Disclosed are low-temperature etching-based metal transfer technology, high-quality source-drain formation technology, and a method of manufacturing a semiconductor device using the same. The method of manufacturing the semiconductor device includes preparing an oxide substrate, sequentially depositing a contact metal, Ti, and Au on the oxide substrate, attaching an organic film on the oxide substrate on which the contact metal, Ti, and Au are deposited, and removing oxide of the oxide substrate.

### CROSS-REFERENCE TO RELATED APPLICATION(S)

This application claims the benefit under 35 USC § 119 (a) of Korean Patent Application No. 10-2023-0157649 filed on Nov. 14, 2023 and Korean Patent Application No. 10-2023-0174602 filed on Dec. 5, 2023 in the Korean Intellectual Property Office, the entire disclosure of which is incorporated herein by reference for all purposes.

### BACKGROUND

### 1. Field

The present invention relates to technology that may transfer all metals through low-temperature etching of a substrate and, more particularly, to technology that may, through the above, determine a type of a semiconductor by inducing Fermi level unpinning during metal/semiconductor bonding.

### 2. Description of Related Art

Currently, research on various types of devices is actively conducted based on transition metal dichalcogen (MoS₂, WS₂, MoTe₂, MoSe₂, ReS₂, ReSe₂, HfS₂, BP, etc.) materials, semiconductor materials receiving great attention as new semiconductor materials that may replace silicon in the future. In particular, as shown in FIG. 1, when directly depositing a metal to form a metal/semiconductor junction in a source/drain region, an arbitrary energy state is formed at the semiconductor interface and two dimensional (2D) semiconductors and bulk semiconductors (Si, Ge, SiGe, GaAs, etc.) are pinned to the arbitrary energy state regardless of the work function of all metals. This is called Fermi level pinning.

Therefore, as shown in FIG. 1, assuming that a pinning location is located at the center of a semiconductor bandgap, an electrical characteristic curve has an ambipolar curve shape with both N-type and P-type.

As such, since the Fermi level pinning phenomenon of a semiconductor is determined as one semiconductor type regardless of the work function of a metal, there is a limitation that it is very difficult to manufacture a complementary metal-oxide semiconductor (CMOS) type of a P-type and N-type semiconductor device composite structure using one channel material on a large-scale wafer.

Technology developed to overcome this limitation is van der Waals (vdW) contact, which is a method of depositing a metal on a separate substrate and attaching the same on a semiconductor source/drain region using a polymethyl methacrylate (PMMA) film to solve a problem that occurs at the semiconductor interface in the process of directly depositing the metal on the semiconductor source/drain region.

As described above, as shown in FIG. 1, if metal vdW contact technology is used, a type of a semiconductor may be determined according to the work function of the metal due to Fermi level unpinning. A metal material with the small work function may exhibit an N-type semiconductor operation and a metal material with the large work function may exhibit a P-type semiconductor operation. As shown in FIG. 1, an electrical characteristic curve may vary depending on the work function of a corresponding metal.

However, the existing metal vdW contact technology relates to technology that forcibly tearing off a dry film and it is impossible to tear off a metal having a strong bonding force with a substrate. In particular, in the case of a Ti metal with the very small work function, a bonding force with a substrate is so strong and accordingly, it is very difficult to perform pick-up.

The present invention proposes technology that may make a vdW contact with all metals through oxide etching of a substrate and, through this, may ultimately determine a type of a semiconductor.

### SUMMARY

The conventional metal transfer technology relates to a method of covering a polymethyl methacrylate (PMMA) film with a metal electrode on a substrate using a spin-coating method and forcibly tearing it off. However, this technology has a risk that the PMMA film is too thin to damage the metal after picking up the metal on the substrate. Therefore, the present invention is to develop pick-up technology that may maintain the quality of metal.

Also, since the conventional technology relates to a method of forcibly pick up a metal on a substrate, it is impossible to pick up a metal with a strong bonding force such as Ti and there is a limitation in technology for determining a semiconductor type. However, the present invention is to develop technology capable of solving this issue.

Also, the conventional metal transfer technology relates to a method of depositing and transferring only a pure contact metal, such as Au and Ag. However, since a metal layer is very thin and its durability is weak, transferring only a necessary metal poses a risk of damaging a metal in a metal pick-up process.

Therefore, the present invention employs a method of performing deposition in the form of a contact metal Ti/Au to strengthen durability of a contact metal. Through this, the durability of the contact metal may be strengthened and oxidation may be prevented through covering using Au metal of an upper layer. That is, the present invention relates to technology that may exhibit more distinct durability.

Also, metal transfer technology proposed in the present invention is to develop technology that may perform all type adjustment in a single semiconductor material by solving the difficulty in preventing Fermi level pinning effect for each next-generation semiconductor material.

That is, the present invention relates to technology for developing a method of performing pick-up by removing substrate oxide in a state in which an organic film of a thick layer is in a simply attached state rather than in a coated state in the process of picking up a metal on a substrate for metal van der Waals (vdW) contact and stably transferring all metals to a source/drain, and to technology for ultimately adjusting a type of a semiconductor.

A method of manufacturing a semiconductor device according to an example embodiment of the present invention includes preparing an oxide substrate; sequentially depositing a contact metal, Ti, and Au on the oxide substrate; attaching an organic film on the oxide substrate on which the contact metal, the Ti, and the Au are deposited; and removing oxide of the oxide substrate.

Transition metal dichalcogen (MoS₂, ReS₂, ReSe₂, WS₂, MoTe₂, WSe₂, BP, MoSe₂, HfS₂, HfSe₂, ZrS₂, ZrSe₂, SnSe₂, SnS₂, etc.) materials, two-dimensional (2D) semiconductor materials receiving great attention as next-generation new materials have the limitation that the Fermi level pinning effect is too strong and the type is determined, making it impossible to use in a complementary metal-oxide semiconductor (CMOS) process. Also, the conventional metal transfer technology for solving this issue may transfer only specific metals and the technology is unstable, making it difficult to guarantee the quality of metal.

The present invention relates to technology that solves all the problems described above and allows all metals to move with maintaining a high-quality film and may adjust a type of semiconductor according to the work function of a metal.

The ability to adjust the type of semiconductor indicates that N-type and P-type operations are possible by manufacturing only a single semiconductor channel material rather than a complicated process of manufacturing N-type and P-type materials separately during a mass production CMOS process on a wafer. Accordingly, significantly groundbreaking effect is expected.

Also, the ability to determine the type of semiconductor indicates that an operation of an inverter, one of logic elements, is possible. Accordingly, the invention is expected to greatly contribute to production of multiple logic circuits.

### BRIEF DESCRIPTION OF THE DRAWINGS

These and/or other aspects, features, and advantages of the invention will become apparent and more readily appreciated from the following description of example embodiments, taken in conjunction with the accompanying drawings of which:

FIG. 1 shows graphs of gate voltage and drain current of the conventional direct metal contact technology and the proposed metal contact technology;

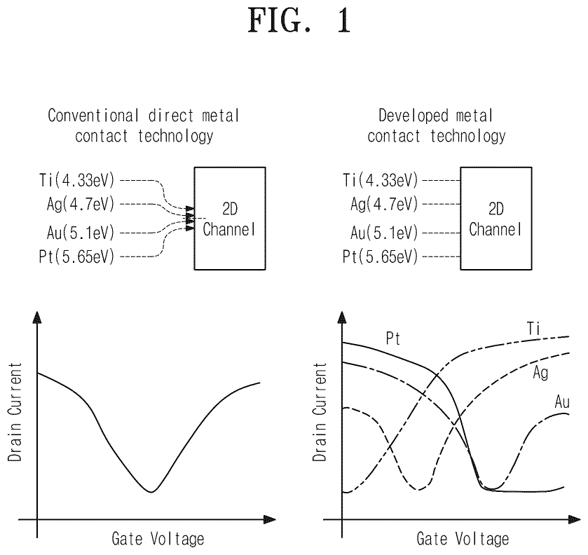

FIG. 2 is a first view for describing the flow of low-temperature etching-based metal transfer technology and high-quality source-drain formation technology;

FIG. 3 is a second view for describing the flow of metal transfer and source-drain formation technology;

FIG. 4 is a view for describing the effect of the proposed metal transfer technology; and

FIG. 5 shows current-voltage graphs in a field effect transistor (FET) manufactured with the proposed technology.

### DETAILED DESCRIPTION

The aforementioned features and effects of the disclosure will be apparent from the following detailed description related to the accompanying drawings and accordingly those skilled in the art to which the disclosure pertains may easily implement the technical spirit of the disclosure.

Various modifications and/or alterations may be made to the disclosure and the disclosure may include various example embodiments. Therefore, some example embodiments are illustrated as examples in the drawings and described in detailed description. However, they are merely intended for the purpose of describing the example embodiments described herein and may be implemented in various forms. Therefore, the example embodiments are not construed as limited to the disclosure and should be understood to include all changes, equivalents, and replacements within the idea and the technical scope of the disclosure.

Although terms of “first,” “second,” and the like are used to explain various components, the components are not limited to such terms. These terms are used only to distinguish one component from another component.

For example, a first component may be referred to as a second component, or similarly, the second component may be referred to as the first component within the scope of the present disclosure. As used herein, the term “and/or” includes any and all combinations of one or more of the associated listed items.

As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, components or a combination thereof, but do not preclude the presence or addition of one or more other features, integers, steps, operations, elements, components, and/or groups thereof.

Hereinafter, example embodiments will be described with reference to the accompanying drawings. However, the scope of the patent application is not limited to or restricted by such example embodiments. Like reference numerals used herein refer to like elements throughout.

The metal transfer technology used in the art was reported for the first time in the world in “Nature volume 557, pages 696 to 700 (2018),” and the metal transfer process started with metal electrodes deposited on a Si substrate having a weak bonding force with deposition materials.

The previously reported technology forms a film by coating a polymethyl methacrylate (PMMA) solution as a thin layer on a metal electrode on a Si substrate through a spin-coating method and then heating the same at 105° C. Then, the metal electrode is separated from the Si substrate by physically picking up the PMMA film. This separated metal electrode is bonded onto a two-dimensional (2D) semiconductor and it is confirmed that a semiconductor type is adjustable due to the Fermi level unpinning effect. Semiconductor source/drain contact technology with this metal transfer technology is called van der Waals (vdW) contact.

However, the previously reported metal transfer technology has many limitations. First, this technology refers to a method of forming the PMMA solution as a thin film with the spin-coating method and then performing pick-up. Therefore, there is a very high risk that the film may be damaged in the pick-up process and accordingly, metal electrodes attached to the film are highly likely to be damaged. Also, after film coating, long-time exposure at high temperature is required to evaporate the liquid phase of the PMMA film, which may change durability of the film.

To solve complexity and process issues found in a PMMA film formation process on a metal electrode and a metal electrode pick-up process, a stamp that combines a poly propylene carbonate (PPC) organic film thicker than PMMA and polydimethylsiloxane (PDMS) is used in the present invention. A film for PPC/PDMS metal transfer may include not only the PPC organic film but also all organic films such as PMMA and PDMS.

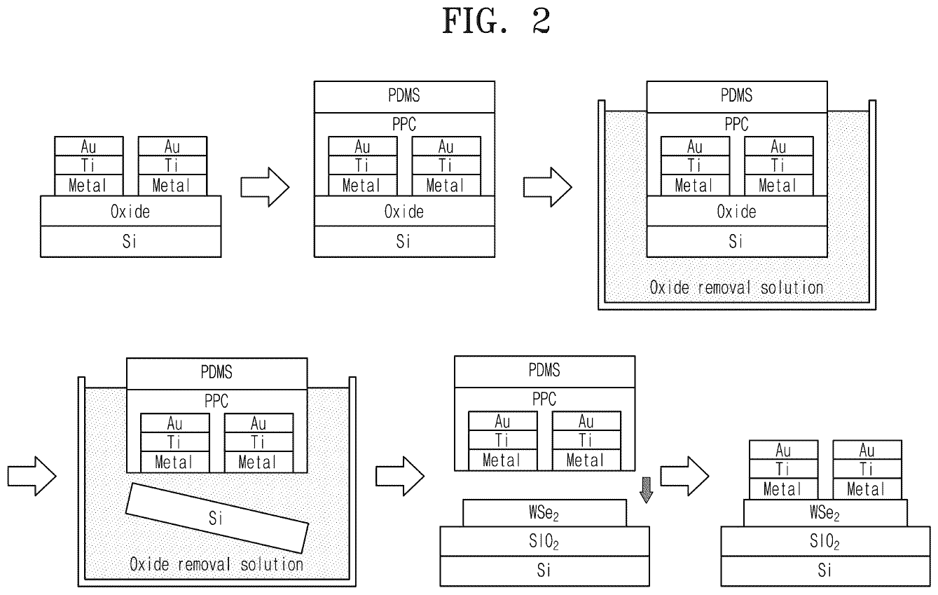

As shown in FIG. 2, the PPC/PDMS stamp does not require a high-temperature process, which differs from a case of using the PMMA film, and may be simply used through attachment on a metal electrode at room temperature. Also, since a thick PPC/PDMS layer is used, a physically applicable force may be greater and damage to the film in a metal pick-up process may be prevented as much as possible.

A second limitation of the existing metal transfer technology is that it is impossible to pick up all metals. To date, metals that may make vdW contact with the metal transfer technology in a semiconductor channel include Ag, Co, Au, Pt, and the like. In general, the metals are functions with large work function. That is, the metals are very advantageous in implementing ambipolar or P-type characteristics in the semiconductor channel.

However, metals with very small work function, such as Ti and Al, have a very strong bonding force with a Si substrate and may not be transferred with the existing metal transfer technology that performs pick-up with the PMMA film, and have a limitation that it is difficult to operate a high-quality N-type semiconductor device.

To outperform the limitations found in the existing metal transfer technology, as shown in FIG. 2, the present invention may pick up and transfer all metals while maintain the quality of metal and PPC/PDMS stamp by covering a PPC/PDMS layer on a metal electrode deposited on an oxide substrate and dipping the same in an oxide removal solution.

In the case of using technology proposed in the present invention, all metals including Ti and Ai may be transferred and the autonomy of vdW contact of the semiconductor device may increase accordingly. Therefore, it is possible to manufacture a CMOS with desired characteristics.

Additionally, a third limitation of the existing metal transfer technology is that metal transfer is generally performed by depositing only pure contact metals Au, Ag, and Cu on the Si substrate. However, if only the pure contact metal is picked up, the quality of the contact metal may be degraded due to its thin thickness and weak durability.

To solve this, as shown in FIG. 2, in the present invention, pick-up is performed through deposition with an appropriately thick thickness in the form of contact metal/Ti/Au, and Ti on the contact metal may maintain the durability of the metal and the top layer Au may prevent oxidation of metals. Accordingly, the quality of metal transfer technology may be improved.

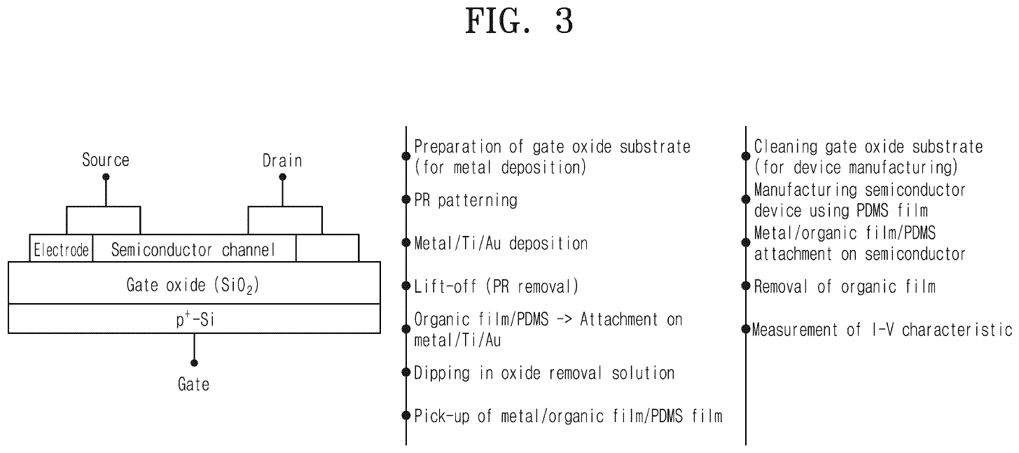

As shown in FIGS. 2 and 3, the metal transfer technology proposed in the present invention performs deposition in the form of metal/Ti/Au on the oxide substrate and covers the PPC/PDMS stamp thereon.

Then, the entire oxide substrate is dipped in an oxide removal solution such as BOE, HF, and nitric acid. In a dipping state, oxide of the oxide substrate is removed and the metal/PPC/PDMS stamp is picked up while maintaining its original shape. That is, the present invention relates to a method of picking up a metal by dipping the metal in an oxide removal solution on a PDMS/PPC/metal/oxide/Si-typed substrate and by etching oxide. The oxide etching solution includes all oxide etchants, such as buffered oxide etchant (BOE), sulfuric acid, formic acid, oxalic acid, BF acid, H₃PO₄:H₂O, HCl, H₂O₂, nitric acid, acetic acid, phosphoric acid, ammonium fluoride, and ammonium hydroxide.

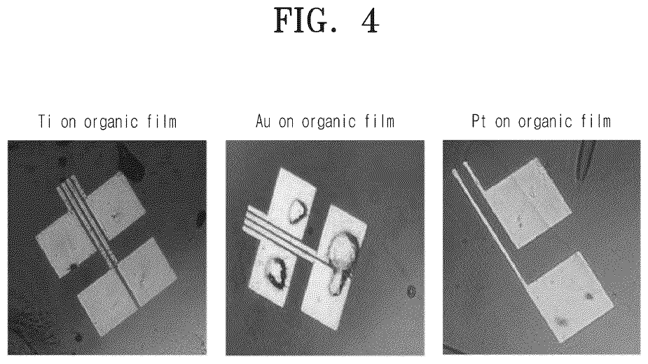

Referring to FIG. 4 showing metals picked up through an oxide etching method with organic film/PDMS stamp, an example embodiment in which various metals, such as Au and Pt, including Ti, which was previously impossible to pick up, are picked up with a PPC film in the form of contact metal/Ti/Au is verified. Also, it is verified that a thin metal electrode with a minimum thickness of 10 μm is maintained. This proves the practical feasibility of the present invention. In addition to Ti, Au, and Pt presented in the example embodiment, examples of the contact metal may include all metals, such as Al, Ag, Cr, V, Mn, Fe, Co, Ni, Nb, Ru, Rh, Hf, Ta, W, Re, TaN, TiN, Er, W, Mo, and Cu.

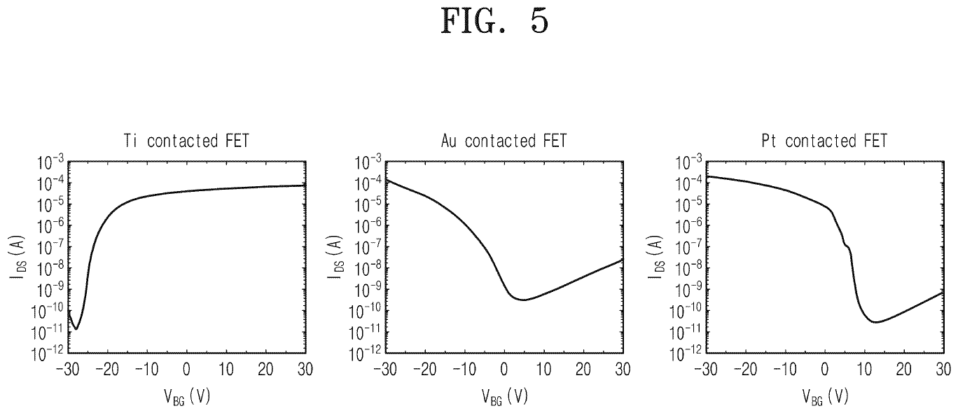

Referring to a process flowchart of FIG. 3, a picked-up metal may be attached to a metal electrode with vdW contact in a source/drain region on a semiconductor channel. Therefore, referring to FIG. 5 showing vdW contacted field effect transistor (FET) device characteristics in the source/drain region of the semiconductor channel with picked-up metals, that in vdW contacted semiconductor devices with picked metals, Ti, Au, and Pt, respectively, semiconductor channels are implemented as N-type, ambipolar, and P-type according to the role of work function of the respective corresponding metals is verified through an example embodiment. In addition to WSez channel presented in the example embodiment, examples of the channel may include all of MoS₂, WS₂, ReS₂, ReSe₂, PtSe₂, HfS₂, MoS₂, HfSe₂, HfTe₅, HfTe₂, ZrS₂, ZrSe₂, ZrTe₂, ZrS₃, ZrS₅, ZrTe₃, MoTe₂, MoSe₂, black phosphorus (BP), 2D tellurium, GeSe, GaSe, GeAs, black AsP, and a-MnS, and examples of bulk semiconductor may include all group III-V semiconductors such as Ge, Si, SiGe and GaAs, GaN, GaP, InP, InAs, and InSb, and organic semiconductors such as pentacene, rubrene, Alq3, tetracene, DFH-4T, perylene, poly[9,9 dioctyl-fluorene-co-bithiophene] (F8T2), poly[2-methoxy-5-(3,7-dimethyloctyloxy)]-1,4-phenylenevinylene (MDMO-PPV), regioregular poly[3-hexylthiophene] (P3HT), polytriarylamine (PTAA), poly-[2,5-thienylene vinylene] (PVT), naphthalene tetracarboxylic diimide (NDI), and perylene diimide (PDI).

The present invention performs a semiconductor channel and source/drain metal formation on a gate insulator (or gate insulating layer), and examples of the gate insulator include all of an oxide film such as SiN, SiO₂, GeO₂, TiO₂, ZnO, ITO, AZO, MgO, Al2O₃, ZrO₂, ZrSiO₄, HfSiO₄, Si₃N₄, SrO, Ta₂O₅, Y₂O₃, HfO₂, La₂O₃, BaO, LaLuO₂, and LaAlO₃, a nitride film, and low/high-k insulator.

Through the example embodiment, it is confirmed that the metal transfer technology of the present invention may easily select a desired type from a single semiconductor material when implemented as a semiconductor device.

The present invention relates to groundbreaking technology that improves the quality of contact metal when picking up a metal using a thick PPC/PDMS stamp and a contact metal/Ti/Au form and enables pick-up of all metals using an oxide etching method.

Also, the present invention relates to technology that may select a semiconductor type in a final semiconductor device in which source and/or drain regions of a semiconductor channel are formed through the invented metal transfer technology.

The proposed method (which may also be referred to as a metal transfer method, a source-drain formation method, and a semiconductor device manufacturing method) is described again with reference to FIGS. 2 and 3.

Initially, a gate oxide substrate (or oxide substrate) is prepared. The prepared gate oxide substrate is a gate oxide substrate for metal deposition and may be referred to as a first gate oxide substrate to be distinguished from a gate oxide substrate for device manufacturing. The first gate oxide substrate may include a Si substrate and an oxide layer.

Photoresist (PR) patterning is performed. This may represent patterning for depositing a contact metal. Then, the contact metal/Ti/Au are sequentially deposited and photoresist is removed, that is, lift off.

An organic film/PDMS stamp may be attached. Then, an oxide material is removed from the gate oxide substrate with the organic/PDMS stamp attached. This may be performed by dipping the oxide substrate in an oxide removal solution. Accordingly, the contact metal/organic film/PDMS film are picked up.

A gate oxide substrate for (semiconductor) device manufacturing is prepared. This gate oxide substrate may be referred to as a second gate oxide substrate to be distinguished from the gate oxide substrate for metal deposition. The second gate oxide substrate may include an Si substrate and a gate oxide layer. Depending on example embodiments, a gate oxide substrate in which a semiconductor channel is formed may be used.

The semiconductor channel is formed on the second gate oxide substrate. A source and/or drain are then formed. The source or the drain may represent the picked-up contact metal/Ti/Au. Here, metal vdW contact technology may be used.

Finally, the organic film is removed. In this manner, the semiconductor device is manufactured. The semiconductor device may include a field-effect transistor (FET), a metal-oxide-semiconductor field-effect transistor (MOSFET), and the like.

While this disclosure includes specific example embodiments, it will be apparent to one of ordinary skill in the art that various alterations and modifications in form and details may be made in these example embodiments without departing from the spirit and scope of the claims and their equivalents. For example, suitable results may be achieved if the described techniques are performed in a different order, and/or if components in a described system, architecture, device, or circuit are combined in a different manner, and/or replaced or supplemented by other components or their equivalents.

Therefore, the scope of the disclosure is defined not by the detailed description, but by the claims and their equivalents, and all variations within the scope of the claims and their equivalents are to be construed as being included in the disclosure.

What is claimed is:

1. A method of manufacturing a semiconductor device, the method comprising:
preparing an oxide substrate;
sequentially depositing a contact metal, Ti, and Au on the oxide substrate;
attaching an organic film on the oxide substrate on which the contact metal, the Ti, and the Au are deposited; and
removing oxide of the oxide substrate.

2. The method of claim 1, wherein the contact metal is one of Ti, Au, Pt, Al, Ag, Cr, V, Mn, Fe, Co, Ni, Nb, Ru, Rh, Hf, Ta, W, Re, TaN, TiN, Er, W, Mo, and Cu.

3. The method of claim 1, wherein the organic film is a poly propylene carbonate (PPC) film or a polymethyl methacrylate (PMMA) film.

4. The method of claim 1, wherein the attaching of the organic film comprises attaching a polydimethylsiloxane (PDMS) film on the organic film.

5. The method of claim 1, wherein the removing of the oxide is performed by dipping the oxide substrate in an oxide removal solution.

6. The method of claim 1, further comprising:
preparing a gate oxide substrate;
forming a channel on the gate oxide substrate;
attaching the contact metal, the Ti, the Au, and the organic film on the gate oxide substrate on which the channel is formed as a source or a drain; and
removing the organic film.

7. The method of claim 6, wherein the channel includes one of WSe₂, MoS₂, WS₂, RcS₂, RcSe₂, PtSe₂, HfS₂, MoS₂, HfSe₂, HfTe₅, HfTe₂, ZrS₂, ZrSe₂, ZrTe₂, ZrS₃, ZrS₅, ZrTe₃, MoTe₂, MoSe₂, black phosphorus (BP), 2D tellurium, GeSe, GaSe, GeAs, black AsP, and a-MnS.
